(19) United States
(12) Patent Application Publication
(10) Pub. No.: US 2025/0174567 A1
(43) Pub. Date: May 29, 2025

(54) GLASS INTERPOSER SEMICONDUCTOR PACKAGE WITH INTEGRATED STACK CAPACITOR AND METHOD OF MANUFACTURING THE SAME

(71) Applicant: SAMSUNG ELECTRONICS CO., LTD., Suwon-si (KR)

(72) Inventors: Yan LI, Santa Clara, CA (US); WooPoung KIM, San Jose, CA (US)

(73) Assignee: SAMSUNG ELECTRONICS CO., LTD., Suwon-si (KR)

(21) Appl. No.: 18/891,844

(22) Filed: Sep. 20, 2024

Related U.S. Application Data
(63) Continuation of application No. 63/603,422, filed on Nov. 28, 2023.

(51) Int. Cl. H01L 23/538; H01L 21/48; H01L 23/00; H01L 23/15; H01L 25/16; H10B 80/00

(52) U.S. Cl. CPC H01L 23/5385; H01L 21/4857; H01L 25/16; H10D 1/68; H01L 23/15; H01L 24/16; H01L 24/32; H01L 24/73; H01L 2224/16227; H01L 2224/32225; H01L 2224/73204; H10B 80/00

(57) ABSTRACT

Provided is a semiconductor package including a glass substrate including a through-glass via, a first redistribution layer on a lower surface of the glass substrate, a second redistribution layer on an upper surface of the glass substrate, and at least one integrated stack capacitor included in at least one of the glass substrate, the first redistribution layer, and the second redistribution layer.

CROSS-REFERENCE TO THE RELATED APPLICATION

This application is based on and claims benefit to U.S. Provisional Application No. 63/603,422 filed on Nov. 28, 2023 in the U.S. Patent and Trademark Office, the disclosure of which is incorporated herein in its entirety by reference.

### BACKGROUND

### 1. Field

Embodiments of the present disclosure relate to a method of manufacturing a semiconductor package with a glass interposer and integrated stack capacitors (ISC) and an apparatus thereof.

### 2. Description of Related Art

As the electronic devices are becoming smaller, a semiconductor package used in the electronic devices also needs to become smaller and have a high reliability together with high performance and high capacity. Accordingly, the importance of the structure of the semiconductor package for responding to the size and performance of the semiconductor package and more stably supplying power to the semiconductor package is increasing.

Information disclosed in this Background section has already been known to the inventors before achieving the disclosure of the present application or is technical information acquired in the process of achieving the disclosure. Therefore, it may contain information that does not form the prior art that is already known to the public

### SUMMARY

One or more one or more embodiments provide a method of manufacturing a semiconductor package with a glass interposer and an integrated stack capacitor, and an apparatus thereof.

According to an aspect of one or more embodiments, there is provided a semiconductor package including a glass substrate including a through-glass via, a first redistribution layer on a first surface of the glass substrate, a second redistribution layer on a second surface of the glass substrate, and at least one integrated stack capacitor included in at least one of the glass substrate, the first redistribution layer, and the second redistribution layer.

According to another aspect of one or more embodiments, there is provided a method of manufacturing a semiconductor package, the method including providing a glass substrate including via, providing a first redistribution layer on a lower surface of the glass substrate, providing a second redistribution layer on an upper surface of the glass substrate, providing an integrated stack capacitor in at least one of the glass substrate, the first redistribution layer, and the second redistribution layer, and providing a semiconductor chip.

According to another aspect of one or more embodiments, there is provided an electronic system including at least one memory configured to store computer-readable instructions and a plurality of data, and at least one processor configured to execute the computer-readable instructions and implement a plurality of computing operations using the data, wherein the at least one processor comprises the semiconductor package includes a glass substrate including a through-glass via, a first redistribution layer on a first surface of the glass substrate, the first redistribution layer including a first redistribution insulating layer, a plurality of first wiring patterns, and a first via, a second redistribution layer on a second surface of the glass substrate, the second redistribution layer including a second redistribution insulating layer, a plurality of second wiring patterns, and a second via, and at least one integrated stack capacitor included in at least one of the glass substrate, the first redistribution insulating layer, and the second redistribution insulating layer.

### BRIEF DESCRIPTION OF DRAWINGS

The above and/or other aspects, features, and advantages of one or more embodiments of the disclosure will be more apparent from the following description taken in conjunction with the accompanying drawings, in which:

FIG. 1 illustrates a semiconductor package according to one or more embodiments;

FIG. 2A illustrates cross-sectional view of providing grooves in a glass substrate,

FIG. 2B illustrates cross-sectional view of providing through-glass tunnels in the glass substrate,

FIG. 2C illustrates cross-sectional view of filling the through-glass tunnel with metal material to form through-glass vias, FIG. 2D illustrates cross-sectional view of providing an integrated stack capacitor (ISC) in one or more of the grooves, FIG. 2E illustrates cross-sectional view of providing redistribution layers on the glass substrate, and FIG. 2F illustrates cross-sectional view of providing vias in the redistribution layers to contact the in a semiconductor package according to one or more embodiments;

FIG. 3A illustrates cross-sectional view of providing a glass substrate including through-glass vias and providing wiring patterns on the glass substrate to contact the through-glass vias, FIG. 3B illustrates cross-sectional view of providing an ISC to contact at least two wiring patterns, FIG. 3C illustrates cross-sectional view of providing redistribution layers on the glass substrate, the wiring patterns, and the ISC, and FIG. 3D illustrate cross-sectional view of providing vias in the redistribution layers and additional wiring patterns on the redistribution layers in a semiconductor package according to one or more other embodiments;

FIG. 4A illustrates an enlarged cross-sectional view of area A in FIG. 3D and

FIG. 4B illustrates an enlarged cross-sectional view of area B in FIG. 3D;

FIG. 5A illustrates cross-sectional view of providing a glass substrate including through-glass vias and providing wiring patterns on the glass substrate to contact the through-glass vias, FIG. 5B illustrates cross-sectional view of providing one or more ISCs on a surface of the glass substrate, FIG. 5C illustrates cross-sectional view of providing redistribution layers on the glass substrate, and FIG. 5D illustrate cross-sectional view of providing vias in the redistribution layers to contact the one or more ISCs and additional wiring patterns on the redistribution layers in a semiconductor package according to one or more other embodiments;

FIG. 6A illustrates an enlarged cross-sectional view of area C in FIG. 5D and

FIG. 6B illustrates an enlarged cross-sectional view of area D in FIG. 5D;

FIG. 7A illustrates cross-sectional view of providing a cavity in a glass substrate including through-glass vias, FIG. 7B illustrates cross-sectional view of providing a semiconductor chip in the cavity, FIG. 7C illustrates cross-sectional view of providing redistribution layers including vias and wiring patterns on the glass substrate, FIG. 7D illustrates cross-sectional view of providing one or more ISCs on the redistribution layers, and FIG. 7E illustrate cross-sectional view of providing additional redistribution a semiconductor package in a glass semiconductor package according to one or more other embodiments;

FIG. 8 illustrates a semiconductor package according to one or more other embodiments;

FIG. 9 illustrates a flowchart of a method of manufacturing a semiconductor package according to one or more embodiments;

FIG. 10 illustrates a semiconductor package architecture that may incorporate the semiconductor packages according to one or more embodiments; and

FIG. 11 illustrates a schematic block diagram of an electronic system according to one or more embodiments.

### DETAILED DESCRIPTION

The embodiments described herein are examples, and thus, the present disclosure is not limited thereto, and may be realized in various other forms. Each of the embodiments provided in the following description is not excluded from being associated with one or more features of another example or one or more other embodiments also provided herein or not provided herein but consistent with the present disclosure. For example, even if matters described in a specific example or embodiment are not described in a different example or embodiment thereto, the matters may be understood as being related to or combined with the different example or, unless otherwise mentioned in descriptions thereof.

In addition, it should be understood that all descriptions of principles, aspects, examples, and embodiments are intended to encompass structural and functional equivalents thereof. In addition, these equivalents should be understood as including not only currently well-known equivalents but also equivalents to be developed in the future, that is, all devices invented to perform the same functions regardless of the structures thereof.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present. Like numerals refer to like elements throughout this disclosure.

Spatially relative terms, such as “over,” “above,” “on,” “upper,” “below,” “under,” “beneath,” “lower,” “top,” and “bottom,” and the like, may be used herein for ease of description to describe one element's relationship to another element(s) as illustrated in the figures. It will be understood that the spatially relative terms are intended to encompass different orientations of a semiconductor device in use or operation in addition to the orientation depicted in the figures. For example, if the semiconductor device in the figures is turned over, elements described as “below” or “beneath” other elements would then be oriented “above” the other elements. Thus, the term “below” can encompass both an orientation of above and below. The semiconductor device may be otherwise oriented (rotated 90 degrees or at other orientations) and the spatially relative descriptors used herein interpreted accordingly.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c. Herein, when a term “same” is used to compare a dimension of two or more elements, the term may cover a “substantially same” dimension.

It will be understood that, although the terms “first,” “second,” “third,” “fourth,” etc. may be used herein to describe various elements, these elements should not be limited by these terms. These terms are only used to distinguish one element from another element. Thus, a first element discussed below could be termed a second element without departing from the teachings of the present disclosure.

It will be also understood that, even if a certain step or operation of manufacturing an apparatus or structure is described later than another step or operation, the step or operation may be performed later than the other step or operation unless the other step or operation is described as being performed after the step or operation. It will be understood that any of the components or any combination of the components described herein may be used to perform one or more the operations of the flowcharts. Further, all operations are example operations, and may include various additional steps.

Embodiments are described herein with reference to cross-sectional illustrations that are schematic illustrations of the one or more embodiments (and intermediate structures). As such, variations from the shapes of the illustrations as a result, for example, of manufacturing techniques and/or tolerances, are to be expected. Thus, the one or more embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present disclosure. Further, in the drawings, the sizes and relative sizes of layers and regions may be exaggerated for clarity.

For the sake of brevity, general elements to semiconductor devices may or may not be described in detail herein.

Due to the high computing performance demands in various applications such as artificial intelligence (AI) applications, a larger package size is required to integrate a greater number of central processing units (CPUs), graphical processing units (GPUs), high bandwidth memories (HBMs), AI chips, etc. in a single semiconductor package. As the thermal design power (TDP) required for CPUs and GPUs increases, a larger package with a relatively low impedance power distribution network (PDN) across multiple frequency ranges, particularly in the high frequency domain, is required.

Semiconductor packages with a glass interposer embedding system-on-chip (SOC) and capacitors such as multilayer ceramic capacitors (MLCC) and silicon-integrated tantalum (Ta) film capacitors have been developed. However, a size of the MLCC and a silicon-integrated Ta film capacitor may be greater than 100 μm.

Semiconductor packages according to one or more embodiments provide integrated stack capacitors being embedded in redistribution layers, build-up layers, or grooves of a glass substrate of the semiconductor package. Accordingly, the vertical size of the semiconductor package and the impedance of the power distribution network (PDN) for multiple frequency ranges, in particular, relatively high frequency ranges, may be reduced to improve performance of the semiconductor package.

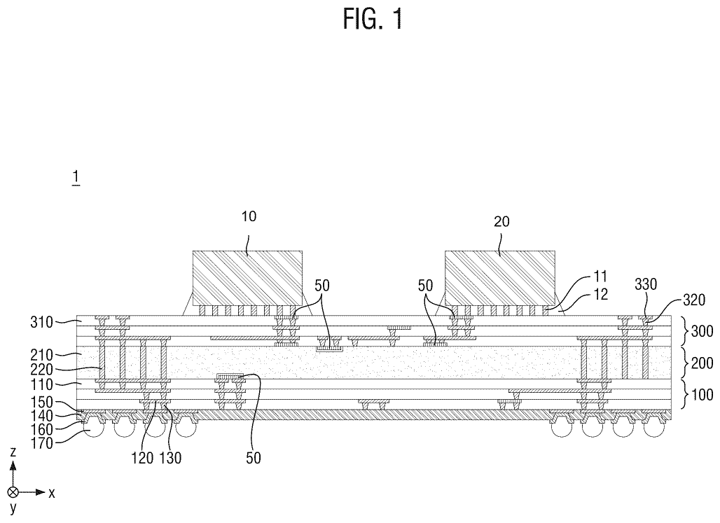

FIG. 1 illustrates a semiconductor package according to one or more embodiments.

Referring to FIG. 1, a semiconductor package 1 may include a first semiconductor chip 10, a second semiconductor chip 20, a first redistribution layer 100, a glass interposer 200, and a second redistribution layer 300. The semiconductor package 1 may be a package having a fan-out structure.

Herein, a direction parallel to a main surface of the first redistribution layer 100 may be referred to as a horizontal direction (X direction and/or Y direction), and a direction perpendicular to the horizontal direction (X direction and/or Y direction) and normal to the main surface of the first redistribution layer 100 may be referred to as a vertical direction (Z direction). The first redistribution layer 100 may include one or more first redistribution insulating layers 110, first wiring patterns 120, and first vias 130. The first wiring patterns 120 and the first vias 130 may be included or enclosed in the first redistribution insulating layers 110. The first redistribution insulating layers 110 may be stack in the vertical direction (Z direction). The first redistribution insulating layer 110 may include an insulating material, such as a photo-imageable dielectric (PID) resin prepared by combining epoxy resin and photoinitiators, and may further include photosensitive polyimide and/or inorganic fillers, not being limited thereto.

The plurality of first wiring patterns 120 and the plurality of first vias 130 may be provided as conductive patterns, and the conductive patterns may be positioned in the first redistribution insulating layer 110. The first wiring patterns 120 may be provided to extend in the horizontal direction (X direction and/or Y direction) in the first redistribution insulating layer 110. The first vias 130 may penetrate one or more first redistribution insulating layer 110 in the vertical direction (Z direction), to contact and be electrically connected with some of the first wiring patterns 120.

According to embodiments, at least some of the first wiring patterns 120 may be integrally provided together with some of the first vias 130. For example, the first wiring patterns 120 and the first vias 130, which are in contact with the upper surface of the first wiring patterns 120, may be integrally formed as a single and continuous structure without an interface therebetween.

According to embodiments, the first vias 130 may have any suitable shape including, for example, a tapered shape in which the horizontal widths of the first vias 130 decrease in the vertical direction (Z direction) away from the first semiconductor chip 10 and the second semiconductor chip 20 depending on the manufacturing conditions.

The first wiring patterns 120 and the first vias 130 may include, for example, metals such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), and an alloy thereof but is not limited thereto.

The semiconductor package 1 may further include a passivation layer 140, an under bump metallurgy (UBM) layer 150, and a conductive layer 160. For example, the passivation layer 140 may have a single-layer structure and may be provided on a lower surface of the lowermost first redistribution insulating layer 110. In one or more other embodiments, the passivation layer 140 may have a multi-layer structure. The passivation layer 140 may at least partially cover an exposed upper surface and an entire side surface of the conductive layer 160 and may expose a lower surface of the conductive layer 160. In addition, the UBM layers 150 may be provided on a portion of the upper surface of the passivation layer 140.

The passivation layer 140 may include an insulating material, for example, an Ajinomoto build-up film (ABF), silicon oxide, silicon nitride, phosphosilicate glass (PSG), borophosphosilicate glass (BPSG), fluorosilicate glass (FSG), and a combination thereof.

The UBM layer 150 may electrically connect the conductive layer 160 with other components of the semiconductor package 1 such as an external connection terminal 170. In addition, the UBM layer 150 may prevent the external connection terminal 170 from cracking due to the thermal shock between the external connection terminal 170 and the first redistribution layer 100, to thereby improve the reliability of the semiconductor package 1. The UBM layer 150 may include a conductive material, for example, copper (Cu), aluminum (Al), silver (Ag), gold (Au), tungsten (W), titanium (Ti), and a combination thereof.

The conductive layer 160 may be provided on the passivation layer 140, and the lower surface of the conductive layer 160 may be exposed from the lower surface of the passivation layer 140. The conductive layer 160 may include conductive patterns that are spaced apart in the first horizontal direction (X direction) or the second horizontal direction (Y direction). In FIG. 1, the conductive layer 160 is shown as single layered conductive patterns that are provided at a single vertical level, however, embodiments are not limited thereto, and the conductive layer 160 may be provided as a multilayered conductive pattern that is provided at different vertical levels depending on embodiments. The conductive layer 160 may include, for example, a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), and ruthenium (Ru), and an alloy thereof but is not limited thereto.

The external connection terminal 170 may be provided on the lower surface of the UBM layer 150. The external connection terminal 170 may be configured to connect the first redistribution layer 100 and an external device electrically and/or physically. The external connection terminal 170 may connect the first semiconductor chip 10 and the second semiconductor chip 20 to a device external to the semiconductor package 1 such as, for example, a module substrate, a system board, and a printed circuit board. According to one or more embodiments, the external connection terminal 170 may include, for example, a solder ball, a conductive bump, and a flip-chip connection structure having a grid array such as a pin grid array, a ball grid array, and a land grid array. The external connection terminal 170 may be electrically connected to the UBM layer 150 and may be electrically connected to the external device such as a module substrate, a system board, and a printed circuit board.

A glass interposer 200 may be provided on an upper surface of the first redistribution layer 100. The glass interposer 200 may include a glass substrate 210 and through-glass vias 220 vertically penetrating the glass substrate 210.

In comparison with material such as silicon (Si) or organic material, glass has greater power integrity performance, and may provide an improved power distribution network (PDN) design and signal integration especially at a relatively high frequency range. Glass may also enable larger packages at a panel level with heterogeneous integration of a chiplet, a central processing unit (CPU), a graphical processing unit (GPU), an artificial intelligence (AI) chip, etc. due to its properties. For example, relative smoothness of glass enables a denser connectivity between chips, adjustable thermal expansion of glass improves reliability, stiffness of glass facilitates manufacturability, zero moisture absorption of glass improves stability, relatively low thermal conductivity of glass isolates hotspots, dielectric insulation property of glass improves signal integration, and as larger area panel processing, for example, at a size of about 150 mm×150 mm, of glass is possible, manufacturing cost may be reduced.

The through-glass vias 220 may be provided between the first redistribution layer 100 and the second redistribution layer 300, and provide an electrical connection path between the first redistribution layer 100 and the second redistribution layer 300. The plurality of through-glass vias 220 may include a conductive material including, for example, copper (Cu), aluminum (Al), silver (Ag), gold (Au), tungsten (W), titanium (Ti), and a combination thereof.

The through-glass vias 220 may have an upper surface and a lower surface spaced apart from each other in the vertical direction (Z direction). The upper surface of the through-glass vias 220 may be coplanar with the upper surface of the glass substrate 210, and the lower surface of the through-glass vias 220 may be coplanar with the lower surface of the glass substrate 210. The through-glass vias 220 may be at least partially in contact with the first vias 130 and first wiring patterns 120 exposed on an upper surface of the uppermost first redistribution insulating layer 110. For example, the lower surfaces of the through-glass vias 220 may be bonded and connected to the upper surface of the first vias 130 and first wiring patterns 120.

Each of the through-glass vias 220 may have any suitable shape including, for example, a cylindrical shape. The diameter of each of the through-glass vias 220 in the horizontal direction (X or Y direction) may be constant along the vertical direction (Z direction). In one or more other embodiments, the plurality of through-glass vias 220 may have tapered shapes having diameters in the horizontal direction (X or Y direction) that vary along the vertical direction (Z direction) depending on the manufacturing conditions.

The second redistribution layer 300 may be positioned on the glass interposer 200. The second redistribution layer 300 may include one or more second redistribution insulating layers 310, second wiring patterns 320, and second vias 330. The second wiring patterns 320 and the second through vias 330 may be included or enclosed in the second redistribution insulating layers 310.

The second redistribution insulating layers 310 may be stack in the vertical direction (Z direction). The second redistribution insulating layer 310 may include an insulating material, such as a photo-imageable dielectric (PID) resin prepared by combining epoxy resin and photoinitiators, and may further include photosensitive polyimide and/or inorganic fillers, not being limited thereto.

The second wiring patterns 320 and the second vias 330 may be provided as conductive patterns, and the conductive patterns may be positioned in the second redistribution insulating layer 310. The second wiring patterns 320 may be provided to extend in the horizontal direction (X direction and/or Y direction) in the second redistribution insulating layer 310. The second vias 330 may penetrate one or more second redistribution insulating layer 310 in the vertical direction (Z direction), to thereby contact and be electrically connected with some of the second wiring patterns 320.

According to embodiments, at least some of the second wiring patterns 320 may be integrally provided together with some of the second vias 330. For example, the second wiring patterns 320 and the second vias 330, which are in contact with the upper surface of the second wiring patterns 320, may be integrally formed as a single and continuous structure without an interface therebetween.

According to embodiments, the second vias 330 may have any suitable shape including, for example, a tapered shape in which the horizontal widths of the second vias 330 decrease in the vertical direction (Z direction) away from the first semiconductor chip 10 and the second semiconductor chip 20 depending on the manufacturing conditions.

The second wiring patterns 320 and the second vias 330 may include, for example, metals such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), and an alloy thereof but is not limited thereto.

The first semiconductor chip 10 and the second semiconductor chip 20 may be provided on the upper surface of the second redistribution layer 300. The first semiconductor chip 10 and the second semiconductor chip 20 may be, for example, a high bandwidth memory (HBM) and a system-on-chip (SOC). However, embodiments are not limited thereto, and semiconductor chips other than an SOC or an HBM, such as, for example, a logic chip such as a central processor (CPU), a graphics processor (GPU), a field programmable gate array (FPGA), a digital signal processor (DSP), an application-specific integrated circuit (ASIC) or a memory chip such as a dynamic random access memory (DRAM) chip and a NAND chip, may be provided.

Connection members 11 may be provided between a lower surface of the first semiconductor chip 10 and an upper surface of the second redistribution layer 300. The lower surface of the first semiconductor chip 10 may include connection pads. The connection pads of the first semiconductor chip 10 may be electrically connected to the second redistribution layer 300 through the connection members 11. An underfill layer 12 may be provided adjacent to and to surround the connection members 11 between the first semiconductor chip 10 and the second redistribution layer 300. Connection members 11 may be provided between active lower surface of the second semiconductor chip 20 and the upper surface of the second redistribution layer 300. The lower surface of the second semiconductor chip 20 may include connection pads. The connection pads of the second semiconductor chip 20 may be electrically connected to the second redistribution layer 300 through the connection members 11. An underfill layer 12 may be provided adjacent to and to surround the connection members 11 between the second semiconductor chip 20 and the second redistribution layer 300. The underfill layer 12 may include a slant outer surface. The underfill layer 12 may include an epoxy resin or two or more silicon hybrid materials.

The semiconductor package 1 may further include one or more integrated stack capacitors (ISC) 50. Each of the one or more ISCs 50 may be a silicon based ISC 50 including a concave array of capacitive vias respectively having a vertical cylinder shape on a silicon backplane. A width in the X direction and the Y direction and a thickness in the Z direction of the ISC 50 may respectively be less than 2 μm. For example, a vertical cylinder array may have a size of 2×2 μm², and the ISC 50 may include concave arrays. For example, a value of capacitance of the ISC 50 may be about hundreds of nF/mm². Accordingly, the ISC 50 may have a relatively small size and a relatively high capacitance density.

Due to the relatively small size of the ISC 50 having a thickness that is equal to or less than 2 μm in the vertical direction (Z direction), the ISC 50 may be provided at various locations in the semiconductor package 1. For example, referring to FIG. 1, as a thickness of a redistribution layer may range from about 3 to 10 μm and is greater than a thickness of the ISC 50, one or more ISCs 50 may be embedded in the second redistribution insulating layer 310, one or more ISCs 50 may be embedded in the first redistribution insulating layer 110 as a land side capacitor (LSC), and one or more ISCs 50 may be provided in the uppermost layer of the second redistribution layer 300 as a die side capacitor (DSC). In addition, one or more ISCs 50 may be provided at grooves formed at an upper surface and/or a lower surface of the glass substrate 210. As described in more detail below, shallow grooves having a depth (thickness) of about 3 to 25 μm in the vertical direction (Z direction) may be manufactured in an upper surface and a lower surface of the glass substrate 210 during a laser grooving process for manufacturing a through-glass via (TGV) 220 in the glass substrate 210. Thus, when placing an ISC 50 in the shallow grooves of the glass substrate 210, a separate step of providing a space to include the ISC 50 in the glass substrate 210 may be omitted and the manufacturing process may be more simplified.

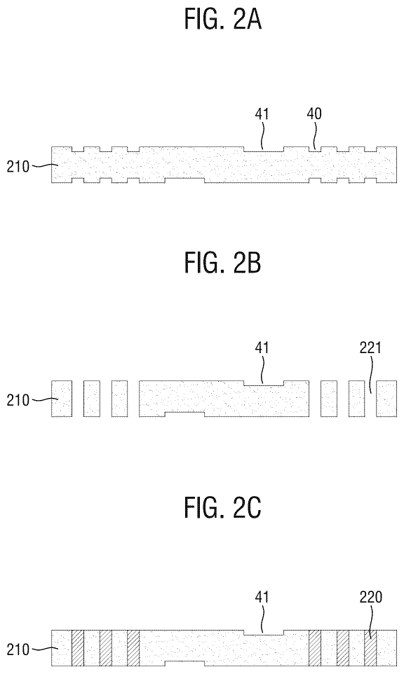

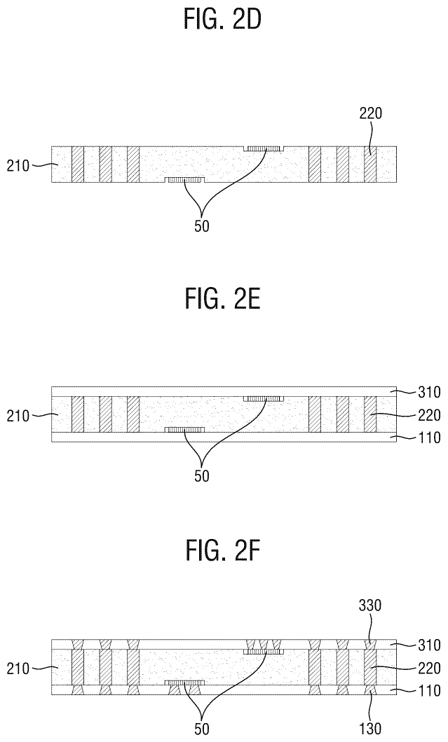

FIGS. 2A through 2F are cross-sectional views illustrating a method of manufacturing a glass interposer and redistribution layers included in a semiconductor package according to one or more embodiments. Descriptions overlapping with previous drawings will be omitted for the sake of brevity and differences will mainly be described. The glass interposer and the redistribution layers manufactured in the method described below may be or correspond to the glass interposer 200 and the redistribution layers 100 and 300 shown in FIG. 1, and thus, the same reference numbers shown in FIG. 1 may be used herebelow.

Referring to FIG. 2A, one or more shallow grooves 41 that have a depth of 3 to 25 μm in the vertical direction (Z direction) are formed through a laser grooving process on a glass substrate 210. A portion of the shallow grooves 41 may be provided to form through-glass vias (TGV) 220 and a remaining portion of the shallow grooves 41 may be provided to embed the one or more ISCs 50 therein.

Referring to FIG. 2B, based on the portion corresponding to the shallow grooves 41, through-glass tunnels 221 may be formed through, for example, wet etching or dry etching.

Referring to FIG. 2C, a metal material is filled in the through-glass tunnels 221 to form through-glass vias 220. The metal material may include a conductive material including, for example, copper (Cu), aluminum (Al), silver (Ag), gold (Au), tungsten (W), titanium (Ti), and a combination thereof. Upper surfaces of the through-glass vias 220 may be coplanar with the upper surface of the glass substrate 210 and lower surfaces of the through-glass via 220 may be coplanar with the lower surface of the glass substrate 210.

Referring to FIG. 2D, one or more ISCs 50 may be provided in the one or more of the shallow grooves 41 provided in the glass substrate 210. For example, the one or more ISCs 50 may be embedded in an upper surface and/or a lower surface of the glass substrate 210. However, embodiments are not limited thereto, and additional ISCs 50 may be embedded inside the glass substrate 210.

Referring to FIG. 2E, the first redistribution insulating layer 110 may be laminated on the lower surface of the glass substrate 210, and the second redistribution insulating layer 310 may be laminated on the upper surface of the glass substrate 210. The first redistribution insulating layer 110 may cover the lower surface of the glass substrate, the lower surface of the through-glass vias 220, and the one or more ISCs 50 embedded in the one or more shallow grooves 41 provided on the lower surface of the glass substrate 210. The second redistribution insulating layer 310 may cover the upper surface of the glass substrate 210, the upper surface of the through-glass vias 220, and the ISCs 50 embedded in shallow grooves 41 provided on the upper surface of the glass substrate 210. According to embodiments, in lieu of the first redistribution insulating layer 110 and the second redistribution insulating layer 310, one or more build-up films may be laminated on the upper surface and the lower surface of the glass substrate 210. The build-up films may include, for example, an Ajinomoto build-up film (ABF).

Referring to FIG. 2F, the first vias 130 may be formed in the first redistribution insulating layer 110 and the second vias 330 may be formed in the second redistribution insulating layer 310. One or more first vias 130 may penetrate one or more first redistribution insulating layer 110 and contact a lower surface of the ISC 50 embedded in a shallow groove 41 provided at a lower surface of the glass substrate 210, and one or more second vias 330 may penetrate one or more second redistribution insulating layer 310 and contact an upper surface of the ISC 50 embedded in a shallow groove provided at an upper surface of the glass substrate 210. An opposite side of the one or more second vias 330 may be connected to one or more second wiring pattern 320, and an opposite side of the one or more first vias 130 may be connected to one or more first wiring pattern 120, as shown in FIG. 1. In addition, the first vias 130 may be provided between and connect two first wiring patterns 120 provided at different vertical levels, and the second vias 330 may be provided between and connect two second wiring patterns 320 provided at different vertical levels, also as shown in FIG. 1. The first vias 130 and the second vias 330 may include, for example, metals such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), and an alloy thereof but is not limited thereto. Additional first redistribution insulating layers 110, first wiring patterns 120, and first vias 130 may be provided, and additional second redistribution insulating layers 310, second wiring patterns 320, and second vias 330 may be provided.

Additional elements, for example, elements as illustrated in FIG. 1 may be provided on the glass interposer and the redistribution layers as illustrated in FIG. 2F.

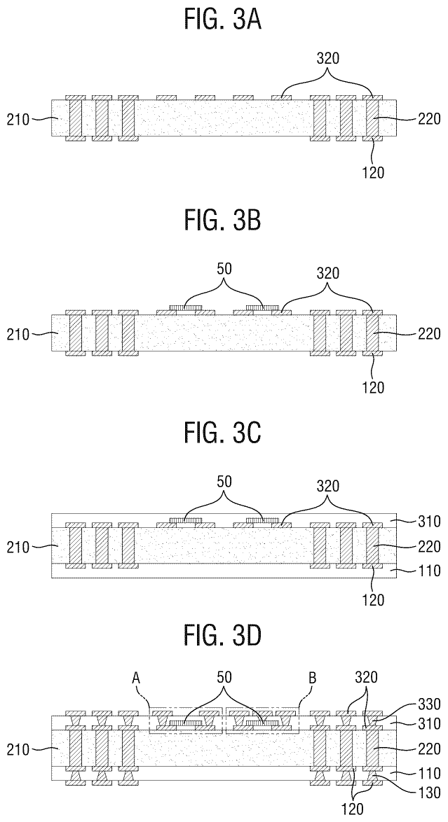

FIGS. 3A through 3D are cross-sectional views illustrating a method of manufacturing a glass interposer and redistribution layers included in a semiconductor package according to one or more other embodiments. Descriptions overlapping with previous drawings will be omitted for the sake of brevity and the differences will mainly be described. The glass interposer and the redistribution layers manufactured in the method described below may be or correspond to the glass interposer 200 and the redistribution layers 100 and 300 shown in FIG. 1, and thus, the same reference numbers shown in FIG. 1 may be used herebelow.

Referring to FIG. 3A, a glass substrate 210 may include through-glass vias 220 formed through a laser grooving process to form shallow grooves on the glass substrate, wet etching process to form through-glass tunnels, and metallization process of filling the through-glass tunnels with a metal material, as described above with reference to FIGS. 2A through 2C. Compared to FIG. 2A, the one or more shallow grooves 41 to embed the one or more ISCs 50 may not be formed. First wiring patterns 120 may be provided on the lower surface of the glass substrate 210 and second wiring patterns 320 may be provided on the upper surface of the glass substrate 210. At least a portion of the first wiring patterns 120 may be provided on at least a portion of the lower surface of the through-glass vias 220 and at least a portion of the second wiring patterns 320 may be provided on at least a portion of an upper surface of the through-glass vias 220, and may provide an electrical path along with the through-glass vias 220.

Referring to FIG. 3B, one or more ISCs 50 may be provided on at least two adjacent second wiring patterns 320. For example, each of the one or more ISCs 50 may contact upper surfaces of at least two adjacent second wiring patterns 320 that are spaced apart from each other and connect the adjacent second wiring patterns 320.

Referring to FIG. 3C, the first redistribution insulating layer 110 may be laminated on the lower surface of the glass substrate 210, and the second redistribution insulating layer 310 may be laminated on the upper surface of the glass substrate 210. The second redistribution insulating layer 310 may cover the first wiring patterns 320 and the one or more ISCs 50, and the first redistribution insulating layer 110 may cover the lower surface of the glass substrate and the first wiring patterns 120. According to one or more embodiments, in lieu of the first redistribution insulating layer 110 and the second redistribution insulating layer 310, one or more build-up films may be laminated on the upper surface and the lower surface of the glass substrate 210.

Referring to FIG. 3D, the first vias 130 may be formed in the first redistribution insulating layer 110 and the second vias 330 may be formed in the second redistribution insulating layer 310. One or more second vias 330 may penetrate one or more second redistribution insulating layer 310 and contact an upper surface of an ISC 50, and an opposite side of the one or more second vias 330 may contact a second wiring pattern 320 as shown in FIG. 1. The first vias 130 may penetrate one or more first redistribution insulating layer 110. In addition, the first vias 130 may be provided between and connect two first wiring patterns 120 provided at different vertical levels, and the second vias 330 may be provided between and connect two second wiring patterns 320 provided at different vertical levels, also as shown in FIG. 1. The plurality of first vias 130 and the plurality of second vias 330 may include, for example, metals such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), and an alloy thereof but is not limited thereto. Additional first redistribution insulating layers 110, first wiring patterns 120, and first vias 130 may be provided, and additional second redistribution insulating layers 310, second wiring patterns 320, and second vias 330 may be provided.

Additional elements, for example, elements as illustrated in FIG. 1 may be provided on the glass interposer and the redistribution layers as illustrated in FIG. 3D.

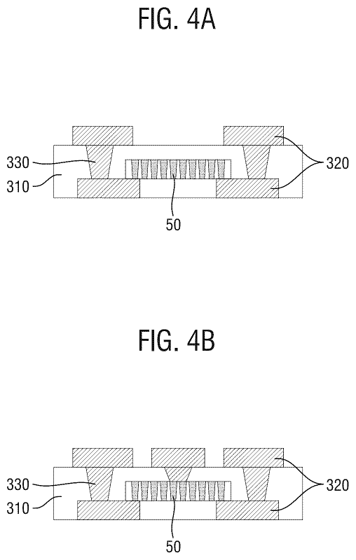

FIG. 4A illustrates an enlarged cross-sectional view of an area A in FIG. 3D and FIG. 4B illustrates an enlarged cross-sectional view of an area B in FIG. 3D.

FIG. 4A illustrates the area A of FIG. 3D illustrating an ISC 50 being embedded in a second redistribution insulating layer 310. The lower surface of the ISC 50 may contact upper surfaces of two adjacent second wiring patterns 320.

FIG. 4B illustrates the area B of FIG. 3D illustrating an ISC 50 being embedded in a second redistribution insulating layer 310. A lower surface of the ISC 50 may contact upper surfaces of adjacent second wiring patterns 320, and an upper surface of the ISC 50 may contact a lower surface of a second via 330.

As illustrated in FIGS. 4A and 4B, the thickness of the ISC 50 which is equal to or less than 2 μm may be less than the thickness of the second redistribution insulating layer 310 which may range from 3 to 10 μm in the vertical direction (Z direction). Accordingly, the ISC 50 may be embedded in the second redistribution insulating layer 310, and the size of the semiconductor package 1 may be reduced.

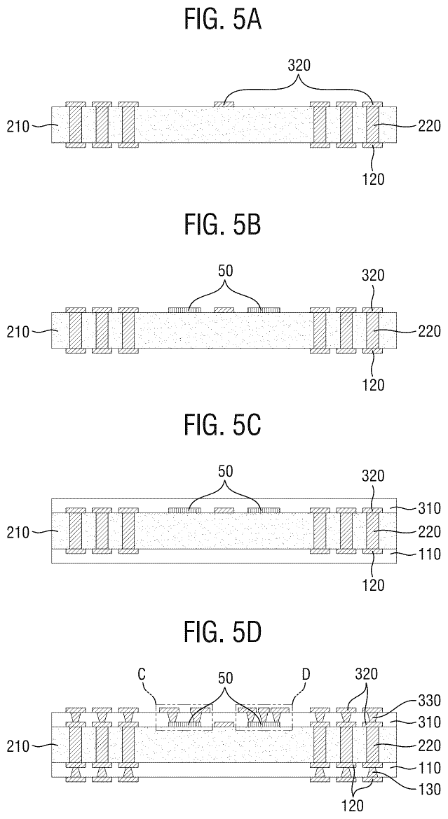

FIGS. 5A through 5D are cross-sectional views illustrating a method of manufacturing a glass interposer and redistribution layers of included in a semiconductor package according to one or more other embodiments. Descriptions overlapping with previous drawings will be omitted for the sake of brevity and the differences will mainly be described. The glass interposer and the redistribution layers manufactured in the method described below may be or correspond to the glass interposer 200 and the redistribution layers 100 and 300 shown in FIG. 1, and thus, the same reference numbers shown in FIG. 1 may be used herebelow.

Referring to FIG. 5A, a glass substrate 210 may include through-glass vias 220 formed through a laser grooving process to form shallow grooves on the glass substrate, wet etching process to form through-glass tunnels, and metallization process of filling the through-glass tunnels with a metal material, as described above with reference to FIGS. 2A through 2C. First wiring patterns 120 may be provided on the lower surface of the glass substrate 210 and second wiring patterns 320 may be provided on the upper surface of the glass substrate 210. At least a portion of the first wiring patterns 120 may be provided on at least partially on the lower surface of the through-glass vias 220 and at least a portion of the second wiring patterns 320 are provided at least partially on the upper surface of the through-glass vias 220, and may provide an electrical path along with the through-glass vias 220.

Referring to FIG. 5B, one or more ISCs 50 may be provided on the upper surface of the glass substrate 210 and adjacent to one or more second wiring pattern 320 provided on the upper surface of the glass substrate 210. For example, a lower surface of the ISC 50 may be coplanar with the upper surface of the glass substrate 210 and a lower surface of the adjacent second wiring pattern 320. However, embodiments are not limited thereto, and additional ISC may be embedded in the glass substrate 210 and/or different layers for the first redistribution insulating layer 110 and the second redistribution insulating layer 310.

Referring to FIG. 5C, the first redistribution insulating layer 110 may be laminated on the lower surface of the glass substrate 210, and the second redistribution insulating layer 310 may be laminated on the upper surface of the glass substrate 210. The second redistribution insulating layer 310 may cover the second wiring patterns 320 and the ISCs 50, and the first redistribution insulating layer 110 may cover the lower surface of the glass substrate and the first wiring patterns 120. According to embodiments, in lieu of the first redistribution insulating layer 110 and the second redistribution insulating layer 310, one or more build-up films may be laminated on the upper surface and the lower surface of the glass substrate 210.

Referring to FIG. 5D, the first vias 130 may be formed in the first redistribution insulating layer 110 and the second vias 330 may be formed in the second redistribution insulating layer 310. The first vias 130 may penetrate one or more first redistribution insulating layer 110 and the second vias 330 may penetrate one or more second redistribution insulating layer 310. The first vias 130 may be provided between and connect two first wiring patterns 120 provided at different vertical level, and the plurality of second vias 330 may be provided between and connect two second wiring patterns 320 provided at different vertical levels as shown in FIG. 1. In addition, one or more second vias 330 may be provided to contact the one or more ISCs 50. For example, a lower surface of the one or more second vias 330 may at least partially contact an upper surface of the ISC 50. The first vias 130 and the second vias 330 may include, for example, metals such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), and an alloy thereof but is not limited thereto. Additional first redistribution insulating layers 110, first wiring patterns 120, and first vias 130 may be provided, and additional second redistribution insulating layers 310, second wiring patterns 320, and second vias 330 may be provided.

Additional elements, for example, elements as illustrated in FIG. 1 may be provided on the glass interposer and the redistribution layers as illustrated in FIG. 5D.

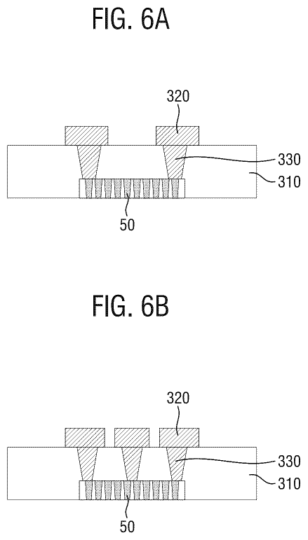

FIG. 6A illustrates an enlarged cross-sectional view of an area C in FIG. 5D and FIG. 6B illustrates an enlarged cross-sectional view of an area D in FIG. 5D.

FIG. 6A illustrates the area C of FIG. 5D illustrating an ISC 50 being embedded in a second redistribution insulating layer 310 and connecting adjacent second vias 330. An upper surface of the ISC 50 may contact lower surfaces of two adjacent second vias 330 and a lower surface of the ISC 50 may contact the glass substrate 210.

FIG. 6B illustrates the area D of FIG. 5D illustrating an ISC 50 being embedded in a second redistribution insulating layer 310 and connecting adjacent second vias 330. An upper surface of the ISC 50 may contact lower surfaces of three adjacent second vias 330 and a lower surface of the ISC 50 may contact the glass substrate 210. As illustrated in FIGS. 6A and 6B, the thickness of the ISC 50 which is equal to or less than 2 μm may be less than the thickness of the second redistribution insulating layer 310 which may range from 3 to 10 μm in the vertical direction (Z direction). Accordingly, as the ISC 50 may be embedded in the second redistribution insulating layer 310, the size of the semiconductor package 1 may be reduced.

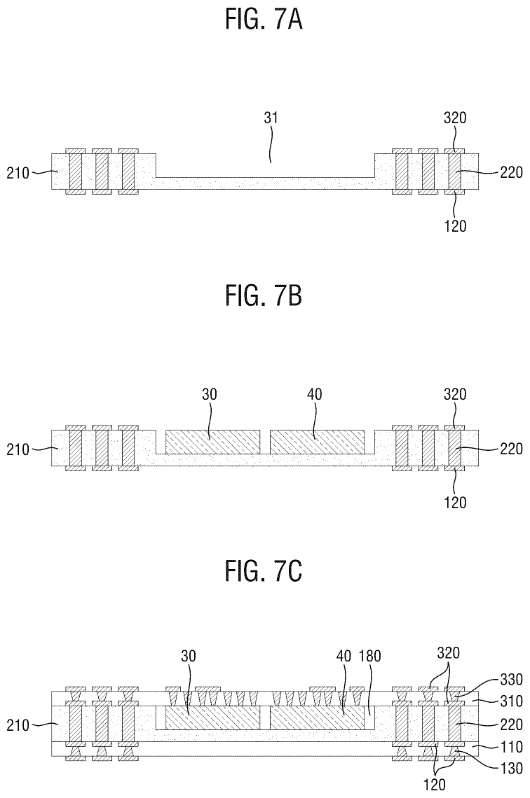

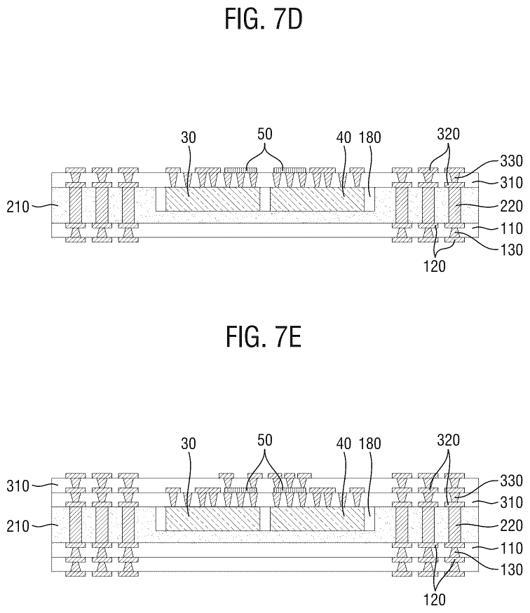

FIGS. 7A through 7E are cross-sectional views illustrating a method of manufacturing a glass interposer and redistribution layers included in a semiconductor package in a glass semiconductor package including system on chips (SOC) according to one or more other embodiments. Descriptions overlapping with previous drawings will be omitted for the sake of brevity and the differences will mainly be described. The glass interposer and the redistribution layers manufactured in the method described below may be or correspond to the glass interposer 200 and the redistribution layers 100 and 300 shown in FIG. 1, and thus, the same reference numbers shown in FIG. 1 may be used herebelow.

Referring to FIG. 7A, a glass substrate 210 may include through-glass vias 220 formed through a laser grooving process to form shallow grooves on the glass substrate, wet etching process to form through-glass tunnels, and metallization process of filling the through-glass tunnels with a metal material, as described above with reference to FIGS. 2A through 2C. First wiring patterns 120 may be provided on the lower surface of the glass substrate 210 and second wiring patterns 320 may be provided on the upper surface of the glass substrate 210. At least a portion of the first wiring patterns 120 may be provided on at least partially on the lower surface of the through-glass vias 220 and at least a portion of the second wiring patterns 320 are provided at least partially on the upper surface of the through-glass vias 220, and may provide an electrical path along with the through-glass vias 220. In addition, one or more cavity 31 may be formed on the upper surface of the glass substrate 210.

Referring to FIG. 7B, a first system on chip (SOC) 30 and a second system on chip (SOC) 40 may be provided in the cavity 31. Referring to FIG. 7C, a molding layer 180 may be fill a space between the cavity 31 and the first SOC 30 and the second system on chip 40. The first redistribution insulating layer 110 may be laminated on the lower surface of the glass substrate 210, and the second redistribution insulating layer 310 may be laminated on the upper surface of the glass substrate 210 and the first SOC 30 and the second system on chip 40. In addition, the first vias 130 may be formed in the first redistribution insulating layer 110 and the second vias 330 may be formed in the second redistribution insulating layer 310. The first vias 130 may penetrate one or more first redistribution insulating layer 110 and the second vias 330 may penetrate one or more second redistribution insulating layer 310. The first vias 130 may be provided between and connect two first wiring patterns 120 provided at different vertical level, and the plurality of second vias 330 may be provided between and connect two second wiring patterns 320 provided at different vertical levels. One or more ISCs 50 may be provided on the second redistribution insulating layer 310 and connected to one or more second vias 330 that are exposed by the second redistribution insulating layer 310. For example, a bottom surface of the ISC 50 may contact an upper surface of the one or more second vias 330. However, embodiments are not limited thereto, and additional ISC may be embedded in the glass substrate 210 and/or different layers for the first redistribution insulating layer 110 and the second redistribution insulating layer 310.

Referring to FIG. 7E, another first redistribution insulating layer 110 may be provided on a bottom surface of the bottom most first redistribution insulating layer 110 and first wiring patterns 120 may be provided on a lower surface of the first redistribution insulating layer 110. First vias 130 may be provided to penetrate the first redistribution insulating layer 110 and contact the first wiring patterns 120. In addition, another second redistribution insulating layer 310 may be provided on an upper surface of the uppermost second redistribution insulating layer 310 and second wiring patterns 320 may be provided on an upper surface of the second redistribution insulating layer 310. Second vias 330 may be provided to penetrate the second redistribution insulating layer 310 and contact the second wiring patterns 320.

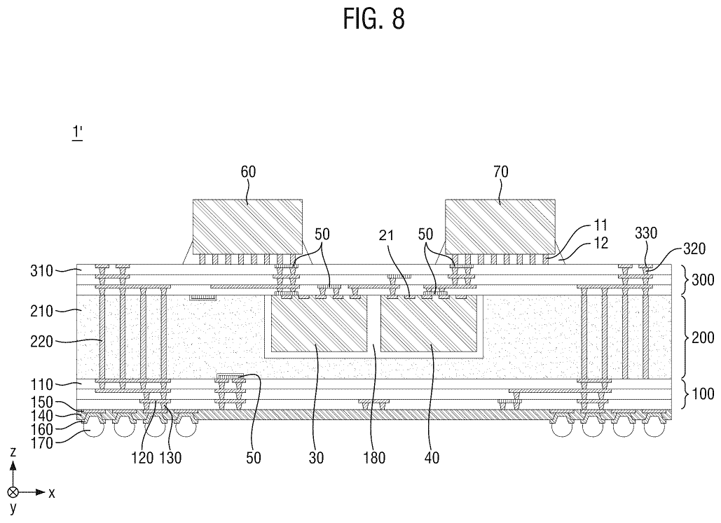

Additional elements, for example, elements as illustrated in FIG. 8 may be provided on the glass interposer and the redistribution layers as illustrated in FIG. 7E.

FIG. 8 illustrates a semiconductor package according to one or more other embodiments. Descriptions overlapping with previous drawings will be omitted for the sake of brevity and the differences will mainly be described.

Referring to FIG. 8, in comparison with the semiconductor package 1 illustrated in FIG. 1, the semiconductor package 1′ may include a first system-on-chip (SOC) 30 and a second system-on-chip (SOC) 40 embedded in the glass substrate 210. For example, the first SOC 30 and the second SOC 40 may be provided in a cavity in the glass substrate 210 adjacent to the through-glass vias 220. The upper surface of the first SOC 30 and an upper surface of the second SOC 40 may be coplanar with an upper surface of the glass substrate 210. Connection pads 21 may be provided on the upper surface of the first SOC 30 and the upper surface of the second SOC 40. Second vias 330 may be connected to the connection pads 21 of the first SOC 30 and a second SOC 40. A molding layer 180 may fill a space between the first SOC 30 and the second SOC 40 and the cavity. The semiconductor package 1′ may further include a first high bandwidth memory (HBM) chip 60 and a second high bandwidth memory (HBM) chip 70 on an upper surface of the second redistribution layer 300. However, embodiments are not limited thereto, and semiconductor chips other than an SOC or an HBM may be provided. For example, a logic chip such as a central processor (CPU), a graphics processor (GPU), a field programmable gate array (FPGA), a digital signal processor (DSP), an application-specific integrated circuit (ASIC) or a memory chip such as a dynamic random access memory (DRAM) chip and a NAND chip, and so on may be provided.

As illustrated in FIG. 8, ISC 50 may be provided at various locations in the semiconductor package 1′. For example, as a thickness of a first redistribution layer 100 and a second redistribution layer 300 may range from about 3 to 10 μm, an ISC 50 may be embedded in the second redistribution insulating layer 310, an ISC 50 may be embedded in the first redistribution insulating layer 110 as a land side capacitor (LSC), and an ISC 50 may be provided in the uppermost layer of the second redistribution layer 300 as a die side capacitor (DSC). In addition, an ISC 50 may be provided at grooves at an upper surface and/or a lower surface of the glass substrate 210.

Referring to FIG. 8, as an ISC 50 may be embedded in the first redistribution insulating layer 110, the second redistribution insulating layer 310, and the glass substrate 210, the ISCs may be provided closer to the first SOC 30, the second SOC 40, the HBM chip 60, and the HBM chip 70, compared to a semiconductor package including, for example, a multilayer ceramic capacitor (MLCC). Thus, the size of the semiconductor package 1′ may be reduced and the impedance of the power distribution network (PDN) for multiple frequency ranges, in particular, relatively high frequency ranges may be lowered and the performance of the semiconductor package 1′ may be improved.

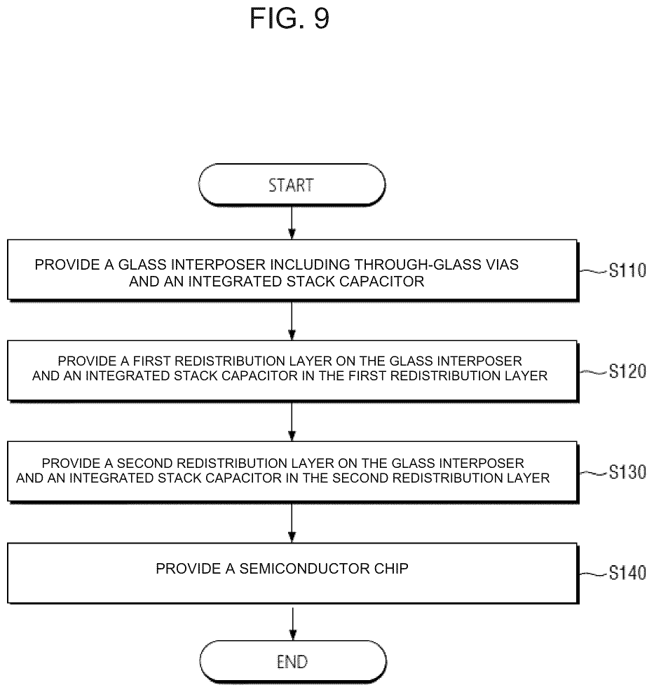

FIG. 9 illustrates a flowchart of manufacturing a semiconductor package according to one or more embodiments.

In operation S110, a glass interposer including a glass substrate and through-glass vias vertically penetrating the glass substrate is formed. The glass substrate is laser processed to form shallow grooves on an upper surface and a lower surface of the glass substrate, and a portion of the shallow grooves are wet etched or dry etched to form through-glass tunnels penetrating the glass substrate. The through-glass tunnels are filled with metal material to form through-glass vias. The metal material may include a conductive material including, for example, copper (Cu), aluminum (Al), silver (Ag), gold (Au), tungsten (W), titanium (Ti), and a combination thereof, but embodiments are not limited thereto. One or more ISCs may be embedded in the one or more shallow grooves and/or cavities of the glass substrate.

In operation S120, a first redistribution layer is formed on the lower surface of the glass interposer. A first redistribution insulating layer is laminated on the lower surface of the glass substrate and the one or more ISCs, and first wiring patterns are formed on first redistribution insulating layer. First vias are formed to penetrate the first redistribution insulating layer, and may connect first wiring patterns provided at different vertical levels and connect one or more first wiring patterns to the ISC. Additional layers of the first redistribution insulating layers with first wiring patterns and first vias may be formed on a lower surface of the first redistribution insulating layer. In addition, the one or more ISCs may be embedded in at least one of the different levels of the first redistribution insulating layers and connected to at least one of a first via and a first wiring pattern. A passivation layer may be formed on a lowermost first redistribution insulating layer. An under bump metallurgy (UBM) layer and a conductive layer may be formed, and an external connection terminal may be formed on the conductive layer to connect the semiconductor package to an external device.

In operation S130, a second redistribution layer is formed on the upper surface of the glass interposer. A second redistribution insulating layer is laminated on the upper surface of the glass substrate and the one or more ISCs embedded in the glass substrate, and second wiring patterns are formed on second redistribution insulating layer. Second vias are formed to penetrate the second redistribution insulating layer, and may connect second wiring patterns provided at different vertical levels and connect one or more second wiring patterns to the one or more ISCs. Additional layers of the second redistribution insulating layers with second wiring patterns and second vias may be formed on an upper surface of the second redistribution insulating layer. In addition, one or more ISCs may be embedded in at least one or the different levels of the second redistribution insulating layers and connected to at least one of a second via and a second wiring pattern.

At operation S140, one or more semiconductor chip may be provided. For example, a semiconductor chip may be provided on the upper surface of the second redistribution layer. Connection members may be formed to connect the semiconductor chip with second wiring patterns included in the second redistribution layer. An underfill layer may fill spaces between the connection members. The semiconductor chip may be a logic chip such as a CPU, a GPU, a FPGA, a DSP, an ASIC or an HBM chip, a DRAM chip, an SRAM chip, a NAND chip, and so on, however, embodiments are not limited thereto. According to one or more other embodiments, SOC chips may also be provided in a cavity formed in the glass substrate prior to forming the first redistribution layer and the second redistribution layer. However, embodiments are not limited thereto, and semiconductor chips other than an SOC chip may be provided in the cavity of the glass substrate. As ISCs may be embedded in the first redistribution insulating layer 110, the second redistribution insulating layer 310, and the glass substrate 210, the ISCs may be provided closer to the semiconductor chips, compared to a semiconductor package including, for example, a multilayer ceramic capacitor (MLCC). Thus, the size of the semiconductor package 1′ may be reduced and the impedance of the power distribution network (PDN) for multiple frequency ranges, in particular, relatively high frequency ranges may be lowered, resulting in an improved he performance of the semiconductor package 1′ may be improved.

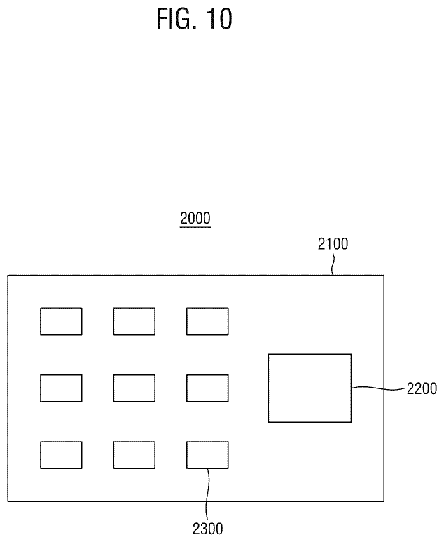

FIG. 10 illustrates a semiconductor package architecture that may incorporate the semiconductor packages according to one or more embodiments.

Referring to FIG. 10, a semiconductor package architecture 2000 according to one or more embodiments may include a processor 2200 and semiconductor devices 2300 that are mounted on a substrate 2100. The processor 2200 and/or the semiconductor devices 2300 may include one or more of semiconductor packages described in the above one or more embodiments.

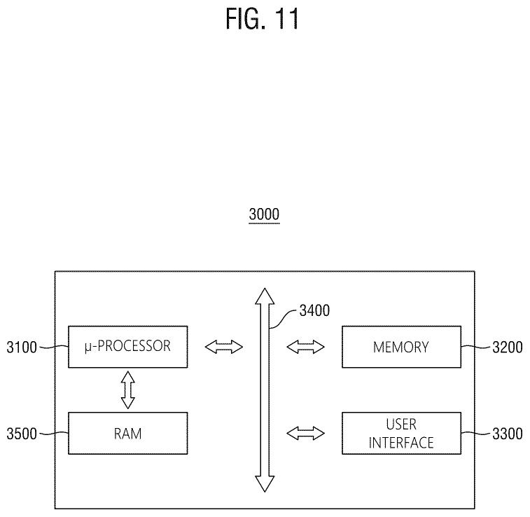

FIG. 11 illustrates a schematic block diagram of an electronic system according to one or more embodiments.

Referring to FIG. 11, an electronic system 3000 in accordance with one or more embodiments may include a microprocessor 3100, a memory 3200, and a user interface 3300 that perform data communication using a bus 3400. The microprocessor 3100 may include a central processing unit (CPU) or an application processor (AP). The electronic system 3000 may further include a random access memory (RAM) 3500 in direct communication with the microprocessor 3100. The microprocessor 3100 and/or the RAM 3500 may be implemented in a single module or package. The user interface 3300 may be used to input data to the electronic system 3000, or output data from the electronic system 3000. For example, the user interface 3300 may include a keyboard, a touch pad, a touch screen, a mouse, a scanner, a voice detector, a liquid crystal display (LCD), a micro light-emitting device (LED), an organic light-emitting diode (OLED) device, an active-matrix light-emitting diode (AMOLED) device, a printer, a lighting, or various other input/output devices without limitation. The memory 3200 may store operational codes of the microprocessor 3100, data processed by the microprocessor 3100, or data received from an external device. The memory 3200 may include a memory controller, a hard disk, or a solid state drive (SSD).

At least the microprocessor 3100, the memory 3200 and/or the RAM 3500 in the electronic system 3000 may include semiconductor packages as described in the above one or more embodiments.

It should be understood that embodiments described herein should be considered in a descriptive sense only and not for purposes of limitation. Descriptions of features or aspects within each embodiment should typically be considered as available for other similar features or aspects in other embodiments.

While embodiments have been described with reference to the figures, it will be understood by those of ordinary skill in the art that various changes in form and details may be made therein without departing from the spirit and scope as defined by the following claims and their equivalents.

What is claimed is:

1. A semiconductor package comprising:
a glass substrate comprising a through-glass via;
a first redistribution layer on a lower surface of the glass substrate;
a second redistribution layer on a upper surface of the glass substrate; and
at least one integrated stack capacitor included in at least one of the glass substrate, the first redistribution layer, and the second redistribution layer.

2. The semiconductor package according to claim 1, wherein the first redistribution layer comprises:
a first redistribution insulating layer;
a plurality of first wiring patterns; and
a first via connecting the plurality of first wiring patterns, and
wherein the second redistribution layer comprises:
a second redistribution insulating layer;
a plurality of second wiring patterns; and
a second via connecting the plurality of second wiring patterns.

3. The semiconductor package according to claim 2, wherein an integrated stack capacitor among the at least one integrated stack capacitor is included in the first redistribution insulating layer, and
wherein the integrated stack capacitor is connected to at least one of the plurality of first wiring patterns and the first via.

4. The semiconductor package according to claim 2, wherein an integrated stack capacitor among the at least one integrated stack capacitor is included in the second redistribution insulating layer, and
wherein the integrated stack capacitor is connected to at least one of the plurality of second wiring patterns and the second via.

5. The semiconductor package according to claim 1, wherein the glass substrate comprises a shallow groove on at least one of an upper surface of the glass substrate and a lower surface of the glass substrate, and
wherein an integrated stack capacitor among the at least one integrated stack capacitor is provided in the shallow groove.

6. The semiconductor package according to claim 2, wherein an integrated stack capacitor among the at least one integrated stack capacitor is on an upper surface of the second redistribution insulating layer.

7. The semiconductor package according to claim 2, wherein an integrated stack capacitor among the at least one integrated stack capacitor is on a lower surface of the first redistribution insulating layer.

8. The semiconductor package according to claim 2, further comprising:
a semiconductor chip on the second redistribution layer; and
a connection member between the semiconductor chip and the second via,
wherein the connection member contacts an integrated stack capacitor among the at least one integrated stack capacitor.

9. The semiconductor package according to claim 1, further comprising:
a system-on-chip included in the glass substrate adjacent to the through-glass vias; and
a connection on an upper surface of the system-on-chip,
wherein the second via is between the connection pad and an integrated stack capacitor among the at least one integrated stack capacitor.

10. The semiconductor package according to claim 2, wherein an integrated stack capacitor among the at least one integrated stack capacitor is included in the second redistribution insulating layer, and
wherein the integrated stack capacitor is on upper surfaces of two adjacent second wiring patterns among the plurality of second wiring patterns.

11. The semiconductor package according to claim 10, wherein an upper surface of the integrated stack capacitor is connected to a lower surface of the second via.

12. The semiconductor package according to claim 2, wherein an integrated stack capacitor among the at least one integrated stack capacitor is included in the second redistribution insulating layer, and
wherein the integrated stack capacitor is on an upper surface of the glass substrate.

13. The semiconductor package according to claim 12, wherein an upper surface of the integrated stack capacitor is connected to a lower surface of the second via.

14. The semiconductor package according to claim 1, wherein a thickness of each of the at least one integrated stack capacitor in a vertical direction is less than or equal to 2 um.

15. A method of manufacturing a semiconductor package, the method comprising:
providing a glass substrate comprising through-glass via;
providing a first redistribution layer on a lower surface of the glass substrate;
providing a second redistribution layer on an upper surface of the glass substrate;
providing an integrated stack capacitor in at least one of the glass substrate, the first redistribution layer, and the second redistribution layer; and
providing a semiconductor chip.

16. The method of claim 15, further comprising:
forming a shallow grooves on at least one of an upper surface of the glass substrate and a lower surface of the glass substrate,
wherein the providing the integrated stack capacitor comprises providing the integrated stack capacitor in at least one of the shallow grooves.

17. The method of claim 15, wherein providing the second redistribution layer comprises providing a second redistribution insulating layer, a plurality of second wiring patterns, and a second via, and
wherein providing the integrated stack capacitor comprises providing the integrated stack capacitor in the second redistribution insulating layer.

18. The method of claim 15, wherein providing the second redistribution layer comprises providing a second redistribution insulating layer, a plurality of second wiring patterns, and a second via, and
wherein providing the integrated stack capacitor comprises providing the integrated stack capacitor in the second redistribution insulating layer and on an upper surface of the glass substrate.

19. The method of claim 15, wherein the providing the semiconductor chip comprises provided the semiconductor chip in at least one of the glass substrate and on a second surface of the second redistribution layer,
wherein the semiconductor chip overlaps the integrated stack capacitor in a vertical direction.

20. An electronic system comprising:
at least one memory configured to store computer-readable instructions and a plurality of data; and
at least one processor configured to execute the computer-readable instructions and implement a plurality of computing operations using the data,
wherein the at least one processor comprises the semiconductor package comprising:
a glass substrate comprising a through-glass via;
a first redistribution layer on a lower surface of the glass substrate, the first redistribution layer comprising a first redistribution insulating layer, a plurality of first wiring patterns, and a first via;
a second redistribution layer on an upper surface of the glass substrate, the second redistribution layer comprising a second redistribution insulating layer, a plurality of second wiring patterns, and a second via; and
at least one integrated stack capacitor included in at least one of the glass substrate, the first redistribution insulating layer, and the second redistribution insulating layer.
